(19) United States
(12) Patent Application Publication
(10) Pub. No.: US 2007/0034973 A1
(43) Pub. Date: Feb. 15, 2007

(54) Methods and Apparatus for Operating a Transistor Using a Reverse Body Bias

(75) Inventors: Eun-jung Yun, Seoul (KR); Sung-young Lee, Gyeonggi-do (KR); Sung-min Kim, Metropolitan City (KR); Dong-gun Park, Gyeonggi-do (KR); Dong-uk Choi, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/461,825

(22) Filed: Aug. 2, 2006

(30) Foreign Application Priority Data
Aug. 9, 2005 (KR) 2005-72999

(51) Int. Cl. H01L 29/76

(52) U.S. Cl. 257/408

(57) ABSTRACT

Some embodiments of the present invention provide methods and apparatus for operating a transistor including at least one fully depleted channel region in and/or on a substrate. The methods include applying a reverse body bias to the substrate when turning on the transistor. The substrate may be a bulk wafer substrate. The reverse body bias may allow the transistor to turn on while preventing turn on of a parasitic transistor in the substrate.

### CROSS-REFERENCE TO RELATED PATENT APPLICATION

This application claims the benefit of Korean Patent Application No. 10-2005-0072999, filed on Aug. 9, 2005, in the Korean Intellectual Property Office, the disclosure of which is incorporated herein in its entirety by reference.

### BACKGROUND OF THE INVENTION

The present invention relates to methods and apparatus for operating transistors and, more particularly, to methods of electrically preventing turning-on of a parasitic transistor formed on a body region of a bulk wafer.

As the application fields of semiconductor devices expand, there is greater demand for densely integrated high-speed semiconductor devices, leading to continuously decreasing design rules. In particular, a channel of a MOS transistor has become shorter and narrower. This may create a short channel effect and a narrow width effect. When the channel length is reduced, the influence of electric potential in a source/drain region to a channel region may be increased. This is called the short channel effect. When the channel width is narrowed, the threshold voltage may be reduced. This is called the narrow width effect.

In order to prevent the short channel effect and the narrow channel effect, various types of MOS transistors have been proposed. For example, a MOS transistor having a fin structure is described in U.S. Pat. No. 6,413,802, a MOS transistor having a fully DEpleted Lean-channel TrAnsistor (DELTA) structure is described in U.S. Pat. No. 4,996,574, and a MOS transistor having a gate all around (GAA) structure is described in U.S. Pat. No. 6,605,847. Furthermore, a MOS transistor having a multi bridge channel (MBC) structure is described in U.S. Patent Application Publication No. 2004-0063286 by the assignee of the present invention. In the MBC structure described therein, channels are vertically stacked with spaces therebetween.

FIGS. 1, 2A and 2B are views of the MOS transistor having a MBC structure as described in U.S. patent publication No. 2004-0063286. FIG. 1 is a plan view, FIG. 2A is a cross-sectional view of the MOS transistor of FIG. 1 taken along a line A-A′, and FIG. 2B is a cross-sectional view of the MOS transistor of FIG. 1 taken along a line B-B′. Referring to FIGS. 1, 2A and 2B, an active pattern 30 is formed on a silicon semiconductor substrate 10. The active pattern 30 includes a channel 44 having a plurality of channels 44a and 44b formed on the semiconductor substrate 10. Source/drain regions 34 are formed on respective sides of the active pattern 30 and connected to the plurality of channels 44a and 44b. A source/drain extension region 32 is formed between the source/drain region 34 and the plurality of channels 44a and 44b.

Tunnels 42 are formed between the channels 44a and 44b. The lower tunnel is formed between the lower channel layer 44a and a high-concentration doping region 12, which is a surface of the semiconductor substrate under the lower channel layer 44a. A groove 42c of a tunnel shape is formed on the upper channel 44b.

The channels 44a and 44b are made of a semiconductor material, such as single crystal silicon, and the source/drain region 34 is made of a conductive material, such as polysilicon. The source/drain extension region 32 extends from the channels and includes the same material of the channels 44a and 44b. It is preferable to form the source/drain extension region 32 of an epitaxial single crystal silicon layer.

A gate electrode 48 is formed on the active pattern 30, surrounding the channels 44a and 4b and filling the groove 42c and the tunnels 42a and 42b. A gate-insulating layer 46 is formed between the gate electrode 48 and the channels 44a and 44b. A metal silicide layer 50 is formed on the gate electrode 48 to reduce gate resistance.

A field region 22 surrounds the source/drain regions 34 except where they join the channel region including the channels 44a and 44b. A high concentration-doping region 12 is formed on the surface of the semiconductor substrate 10 under the active pattern, that is, under the lower channel 44a. The high concentration-doping region 12 includes impurity ions of a conductivity type different from that of the source/drain regions 34. The high concentration-doping region 12 may be formed by injecting a high concentration of impurity ions of the same conductive type as the semiconductor substrate 10. The high concentration-doping region 12 may be formed before or after forming the channels 44a and 44b.

As shown in FIG. 2A, the source/drain regions 34 and a body region of the semiconductor substrate 10 formed therebetween form a parasitic transistor in a horizontal direction while forming a p-n junction in a reverse direction. Since punch-through may occur through these regions, the high concentration-doping region 12 may prevent the parasitic transistor from operating when the normal transistor is turned on through the channels 44a and 44b. The high concentration impurity ions in the high concentration-doping region 12 may increase the threshold voltage of the parasitic transistor. That is, the formation of the high concentration-doping region 12 may be viewed as a kind of a channel isolation technique to prevent a transistor channel from forming in these regions.

FIG. 3 is a cross sectional view of a fin MOSFET according to the related art. Referring to FIG. 3, a semiconductor substrate 310 has a projecting portion having a fin shape. A fin structure is formed projecting from the surface of the semiconductor substrate 310. A first insulating layer 312 and a second insulating layer 314 are formed on the semiconductor substrate 310 including a part of the projecting portion, and a gate-insulating layer 318 is formed on the side surfaces and the upper surface of the projecting portion of the semiconductor substrate 10. A gate electrode 320 is formed on the gate-insulating layer 318. A reference numeral 316 denotes an inter-layer insulation layer.

As shown in FIG. 3, a high concentration impurity-doping region 322 is formed at a lower portion of the projecting portion where a channel region is to be formed. The high concentration impurity-doping region 322 may be formed by injecting a high concentration of impurity ions of the same conductive type as the semiconductor substrate 310. The high concentration impurity-doping region 322 may prevent degradation of element performance caused by activated parasitic transistors in these regions, similar to the high concentration impurity-doping region 12 shown in FIG. 2A.

Because the high concentration impurity doping regions 12 and 322 may be formed by injecting impurity ions with a high concentration to isolate a channel, junction breakdown voltage characteristics between the source region and the drain region may be degraded. Also, because the distance between the source/drain region 34 and the high concentration impurity doping region 12 is reduced in proportion to the size of the semiconductor device, it may be very difficult to prevent punch-through in these regions by using only a high concentration impurity doping region as described above. Furthermore, in order to form the high concentration impurity doping regions such as the regions 12 and 322 for channel isolation, an additional process may be needed to inject impurity ions, which may complicate the manufacturing process and increase costs.

If a high concentration impurity-doping region is formed before forming normal transistors, the impurities in the high concentration impurity-doping region may diffuse into the body region during subsequent thermal processes. This may make controlling electrical characteristics difficult. Moreover, the channel region and the semiconductor substrate may be damaged by the ion injecting process when the high-concentration doping region is formed after the channel of the transistor.

### SUMMARY OF THE INVENTION

Some embodiments of the present invention provide methods and apparatus for operating a transistor to prevent turning-on of a parasitic transistor formed on a substrate. Some embodiments of the present invention also provide methods of operating a transistor to prevent degradation of performance caused by a parasitic transistor without additionally doping a body region with impurity ions for channel isolation in the transistor including a floating channel region floated from the body region of a substrate. Some embodiments of the prevent invention further provide methods of operating a transistor to prevent degradation of performance caused by a parasitic transistor without additionally doping a body region with impurity ions for channel isolation in a transistor including a fully depleted channel region connected to a body region of a substrate.

Some embodiments of the present invention provide methods and apparatus for operating a transistor including at least one fully depleted channel region in and/or on a substrate. The methods include applying a reverse body bias to the substrate when turning on the transistor. The substrate may be a bulk wafer substrate. The reverse body bias may allow the transistor to turn on while preventing turn on of a parasitic transistor in the substrate.

The fully depleted channel region may include a floating channel region. The floating channel region may include a plurality of vertically or horizontally disposed floating channel regions. The floating channel region may be surrounded by a gate electrode, and a gate-insulating layer may be interposed between the floating channel region and the gate electrode.

The fully depleted channel region may be disposed in a fin-shaped region contiguous with the substrate. A source region and a drain region of the transistor may be disposed on respective sides of the fin-shaped region. A groove may be disposed in an upper surface of the fully depleted channel region.

The reverse body bias may be sufficient to increase a threshold voltage of the parasitic transistor to above a threshold voltage of the transistor. The transistor may be a PMOS field effect transistor or a NMOS field effect transistor.

In further embodiments of the present invention, methods and apparatus are provided for operating a transistor including spaced-apart source and drain regions in an active region of a substrate, at least one floating channel region floated with respect to a body region of the substrate and disposed between the source region and the drain region, and a gate electrode on the channel region. The transistor is turned on while applying a reverse body bias to the body region to increase a threshold voltage of a parasitic transistor in the body region.

In some embodiments, the transistor may not include a high concentration-doping region underlying the floating channel region. The reverse body bias may prevent turn-on of the parasitic transistor when the transistor is on. The reverse bias may increase a threshold voltage of the parasitic transistor to a level greater than a threshold voltage of the transistor. The transistor may be a PMOS field effect transistor or an NMOS field effect transistor.

The transistor may include a plurality of vertically or horizontally disposed floating channel regions. The gate electrode may surround the floating channel region, and a gate insulation layer may be interposed between the gate electrode and the floating channel region.

Further embodiments of the present invention provide methods and apparatus for operating a transistor including spaced apart source and drain regions disposed on respective sides of a fin-shaped region contiguous with a body region of a substrate, and a gate electrode on the fully depleted channel region, the fin-shaped region contacting a body region of the substrate and supporting a fully depleted channel region between the source region and the drain region when the transistor is on. The transistor is turned on while applying a reverse body bias to the body region to increase a threshold voltage of a parasitic transistor in the body region.

In some embodiments, a high concentration impurity-doping region is not disposed under the fully depleted channel region in the transistor. The transistor may include a groove on an upper surface of the fully depleted channel region of the fin shaped region. The transistor may be a PMOS field effect transistor or an NMOS field effect transistor.

The reverse body bias may prevent turn-on of the parasitic transistor. The reverse body bias may increase a threshold voltage of the parasitic transistor to a level greater than a threshold voltage of the transistor.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view of a MOSFET having a multiple channel according to the related art;

FIG. 2A is a cross-sectional view of the MOSFET of FIG. 1 taken along a line A-A′;

FIG. 2B is a cross-sectional view of the MOSFET of FIG. 1 taken along a line B-B′;

FIG. 3 is a cross-sectional view of a fin MOSFET according to the related art;

FIG. 4 is a perspective view of a fin MOSFET and control circuit therefor;

FIG. 5A is a cross-sectional view of the MOSFET of FIG. 4 taken along a line B-B′;

FIG. 5B is a magnified view of a portion A in FIG. 5A;

FIG. 6 is a cross-sectional view of the MOSFET of FIG. 4 taken along a line A-A′;

FIG. 7 is a cross-sectional view of a MOSFET having a multiple floating channel and a control circuit therefor;

FIG. 8 is a cross-sectional view of a modified fin MOSFET;

FIG. 9 is a graph showing I_{D}-V_{G} characteristics of a fin PMOSFET operated according to some embodiments of the present invention;

FIG. 10 is a graph showing I_{D}-V_{G} characteristics of a floating channel PMOSFET operated according to some embodiments of the present invention; and

FIG. 11 is a graph showing threshold voltage characteristics of a floating channel PMOSFET operated according to some embodiments of the present invention.

### DETAILED DESCRIPTION OF EMBODIMENTS OF THE INVENTION

The present invention will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments and is not intended to be limiting of the invention. As used herein, the singular forms “a”, “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the present invention are described herein with reference to perspective illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will also be appreciated by those of skill in the art that references to a structure or feature that is disposed “adjacent” another feature may have portions that overlap or underlie the adjacent feature.

Methods of operating transistors according to some embodiments of the present invention can be applied to a transistor on a bulk wafer substrate. A transistor formed on a silicon-on-insulator (SOI) wafer substrate may include an activation region formed on a buried oxide layer, and the activation region may include a fully depleted channel region. Accordingly, no body effect may arise in the transistor formed on SOI wafer substrate. However, if a “normal” transistor is formed on a bulk wafer substrate, a parasitic transistor may be formed on a body region of the bulk wafer substrate. Some embodiments of the present invention relate to methods of operating such a normal transistor without turning on the parasitic transistor.

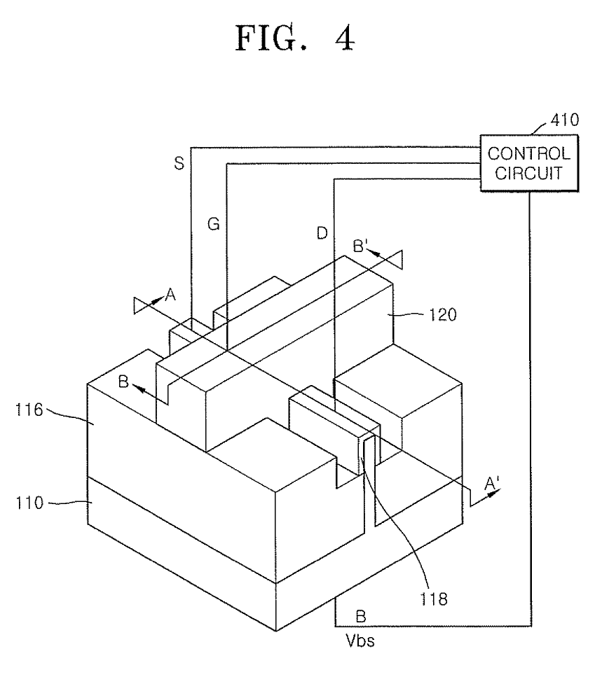

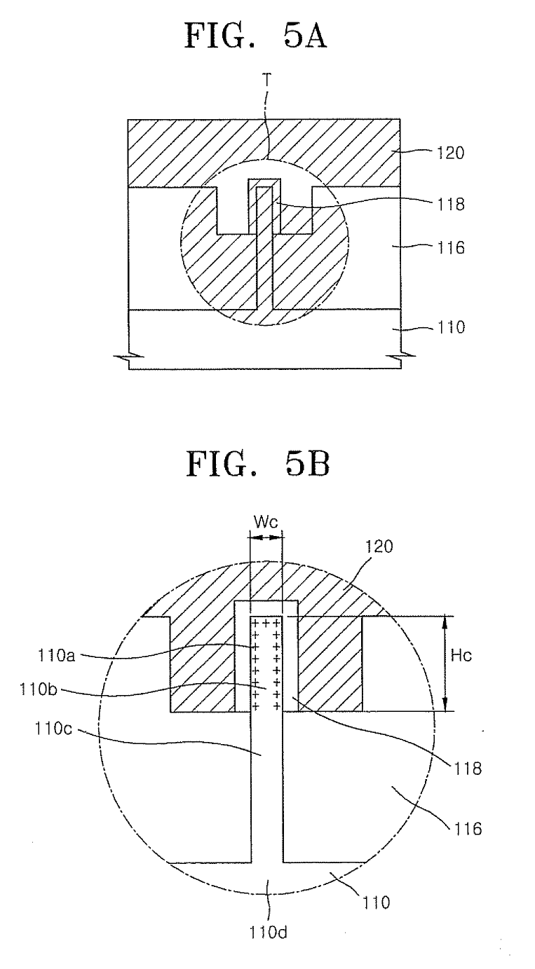

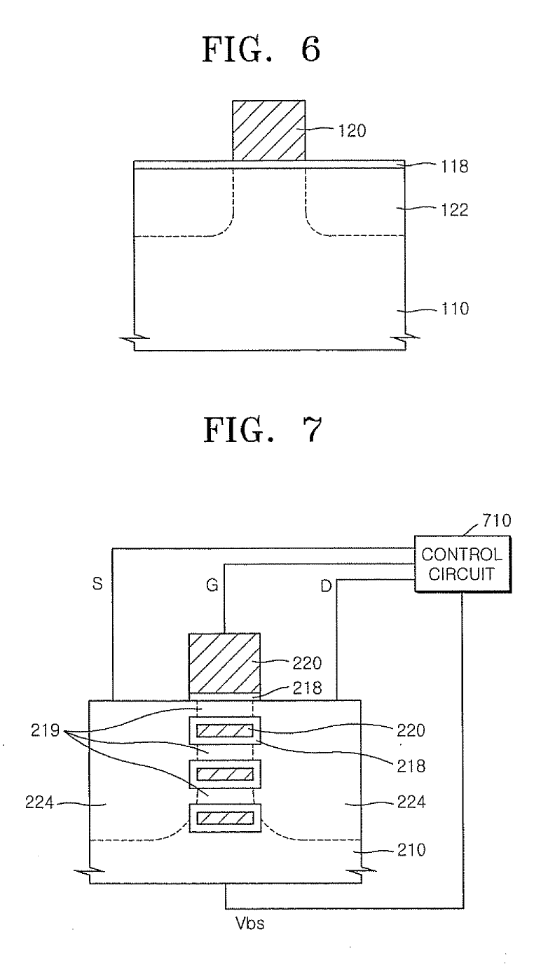

Some embodiments of the present invention will now be described for a transistor having a floating channel region floated with respect to a body region of a bulk wafer substrate, and a transistor having a fully depleted channel region connected to a body region. FIG. 4 is a perspective view of a fin-type MOSFET to in which some embodiments of the present invention may be implemented, and FIG. 5A is a cross-sectional views of the MOSFET of FIG. 4 taken along a line B-B′. FIG. 5B is a magnified view of a portion T in FIG. 5A, and FIG. 6 is a cross-sectional view of the MOSFET of FIG. 4 taken along a line A-A′.

A fin-type metal oxide semiconductor (MOS) field effect transistor (FET), which is a transistor having a fin structure, will now be described with reference to FIGS. 4 through 6. A bulk wafer semiconductor substrate 110 includes a fin structure 110C shown in FIG. 5B, protruding along a first direction. The fin structure is contiguous with (e.g., grown up from) a region of the semiconductor substrate 110, for example, a body region 110d. A device isolation layer 116 is formed adjacent the fin structure and the body region 110d of the semiconductor substrate 110.

A gate insulation layer 118 is formed on an end part of the fin structure, and a gate electrode 120 is formed on the gate insulating layer 118 and the device isolation layer 116. The gate electrode 120 surrounds the gate insulation layer 118 and extends in a second direction orthogonal to the first direction. As shown in FIG. 6, Source/drain regions 122 are formed at respective sides of the gate electrode 120, and impurity ions are implanted into the source/drain region 122s.

FIG. 5A is a cross-sectional view of the MOSFET of FIG. 4 taken along a line B-B′. As shown in FIG. 5A, the fin-type MOSFET does not include a high concentration-doping region such as the region 322 in the conventional fin-type MOSFET shown in FIG. 3. FIG. 5B is a magnified view of a portion T of FIG. 5A. The operation of forming a fully depleted channel region in the fin structure for PMOS will now be described. In FIG. 5B, a reference character Wc denotes the width of a channel region and a reference character Hc denotes a channel height.

When a negative voltage is supplied to the gate electrode 120, a fully depleted region 10b is formed at the upper portion of the fin structure 110c surrounded by the gate electrode 120. The fully depleted region 110b is formed around the side surface and the upper surface of the fin structure 110 facing the gate electrode 120. As the gate voltage continually increases, the fully depleted region 10b extends from the both side surface and the upper surface to the center of the fin structure 110c. When the gate voltage reaches a threshold voltage, the depleted region 110b reaches its maximum width. That is, the depleted region 110b has the maximum width when the gate voltage reaches the threshold voltage. If the width Wc of the channel region shown in FIG. 5B is less than the maximum width, the entire channel region in the upper portion of the fin structure 110c becomes the fully depleted region. A numeral reference 110a denotes induced carriers adjacent to the gate insulation layer 118.

As shown in FIG. 4, a control circuit 410 may be configured to provide voltages to source S, gate G, drain D and body B terminals of the transistor of FIG. 4. In particular, the control circuit 410 may be configured to provide a reverse body bias V_{BS} to the body terminal B while turning on the transistor, as discussed in greater detail below.

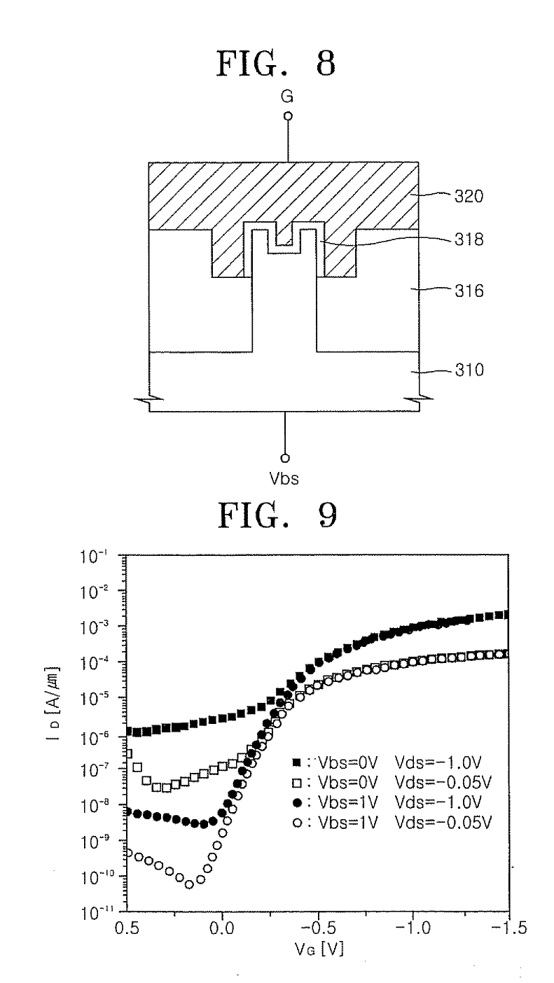

FIG. 8 shows a fin-type MOSFET in which some embodiments of the present invention may be implemented. In particular, FIG. 8 illustrates a multi-channel FET (MCFET) structure. As shown in FIG. 8, a groove is formed on an upper surface of a fin structure to widen a contact surface with a gate electrode 320. The fin structure of the fin-type MOSFET has a full depletion channel region similar to the fin-type MOSFET shown in FIG. 5A, and a portion of the fin structure is connected to a body region of the semiconductor substrate 310. Operations described with reference to FIGS. 5A and 5B also apply to the fin-type MOSFET of FIG. 8. Therefore, further detailed description thereof is omitted.

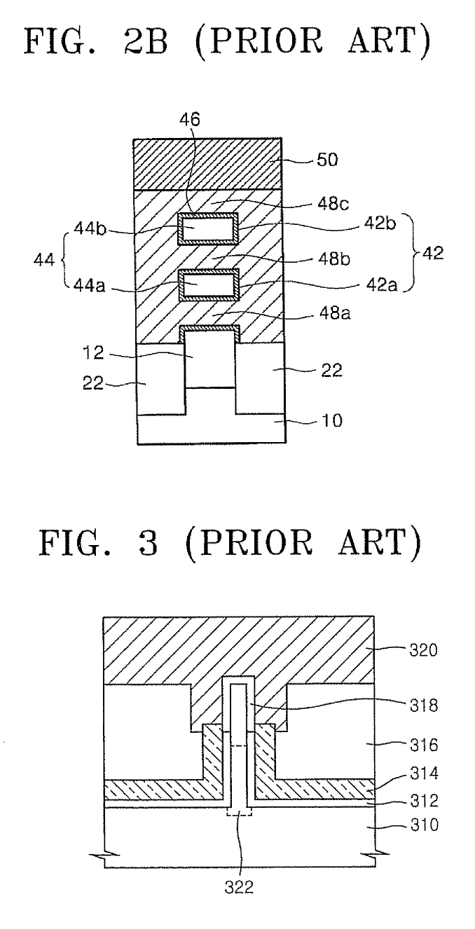

FIG. 7 is a cross-sectional view of a MOSFET having a multi floating channel in some embodiments of the present invention may be implemented. The MOSFET structure in FIG. 7 includes a transistor having a floating channel region that floats with respect to a body region, which is not in the conventional MOSFET shown in FIG. 2A. Compared to the conventional MOSFET shown in FIG. 2A, the multi-floating channel MOSFET of FIG. 7 does not include a high concentration-doping region, such as the region 12 in the MOSFET of FIG. 2A, formed at the body region under the lower portion of the channel region surrounded by the gate electrode 220.

As shown in FIG. 7, multiple floating channel regions 219 are formed vertically in an active region of a semiconductor substrate 210 and separated from the body region. The floating channel regions 219 are surrounded by a gate electrode 220, and a gate insulation layer 218 is interposed therebetween. The multiple floating channel regions 219 are connected to source/drain regions 224 formed at respective sides of the gate electrode 220. The floating channel regions 219 provide a fully depleted channel region.

As shown in FIG. 7, a control circuit 710 may be configured to provide voltages to source S, gate G, drain D and body B terminals of the transistor of FIG. 7. In particular, the control circuit 710 may be configured to provide a reverse body bias V_{BS} to the body terminal B while turning on the transistor, as discussed in greater detail below.

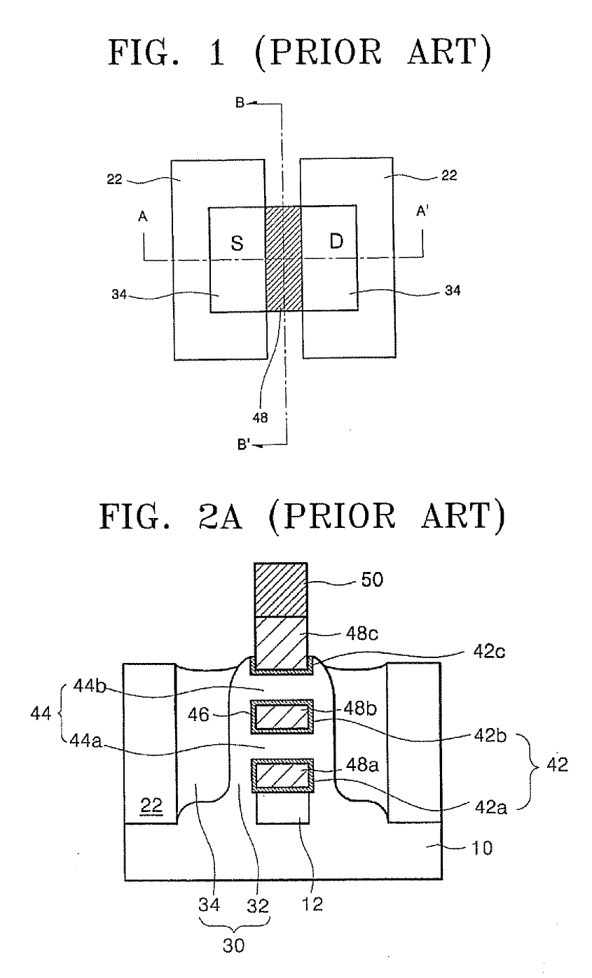

Some embodiments of the present invention may be applied to a transistor having a bulk wafer semiconductor substrate. In some embodiments of the present invention, a reverse body bias (Vbs) is applied, e.g., to a rear surface of a semiconductor substrate, such as the semiconductor substrates 110, 210, 310 in FIGS. 4, 7 and 8, when turning on the transistor. This may reduce or prevent turning-on of a parasitic transistor formed on a body region, without influencing the normal transistor formed in a floating channel region or a full depletion channel region. Therefore, a high impurity concentration region, such as provided in the devices shown in FIGS. 1, 2A and 2B, may not be needed for channel isolation.

As it may be desirable that the normal transistor using the floating channel region or the fully depleted channel region turn on at the threshold voltage and the parasitic transistor not turn on at the threshold voltage, in some embodiments, the magnitude of the reverse body bias voltage may be greater than or equal to that of the threshold voltage. In further embodiments, the magnitude of the reverse body bias voltage may be less than that of the threshold voltage of the normal transistor in a range that can increase a threshold voltage of the parasitic transistor.

FIG. 9 is a graph showing I_{D}-V_{G} characteristics of a fin-type PMOSFET according to some embodiments of the present invention. The fin-type PMOSFET does not include a high-concentration doping region as a channel isolation region. The graph shows the I_{D}-V_{G} characteristics with a reverse body bias (Vbs=1 V) and without a reverse body bias (Vbs=0 V). Drain-to-source voltages (Vds) of −0.05V and −0.1V are applied in each case.

As shown in FIG. 9, a junction leakage current may be dramatically reduced when the reverse body bias is applied to the fin-type PMOS transistor comparing to when such a reverse body bias is not applied. The graph also shows that the drain current ID is not significantly less when the transistor is “on” when the reverse body bias is applied to the body region.

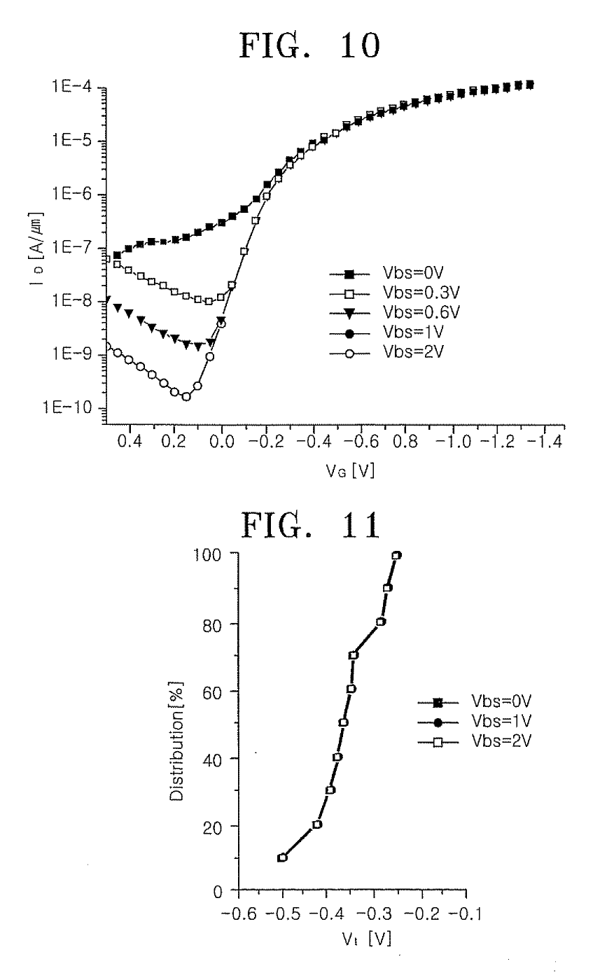

FIG. 10 is a graph showing drain current I_{D}-gate voltage VG characteristics of an MBC-type floating channel PMOSFET operated according to some embodiments of the present invention. In particular, the graph shows the I_{D}-V_{G} characteristics without a body bias (Vbs=0) and with a reverse body bias (Vbs=0.3V, 0.6V, 1V, and 2V). Drain voltages (Vds) of −0.05V and −0.1V are applied in each case. The length of the gate is 35 nm and the width of the gate is 90 nm. The thickness of the gate insulation layer is 1.7 nm, and TiN is used as a gate electrode.

As shown in FIG. 10, the junction leakage current may be dramatically reduced when the reverse body bias is applied to the MBC-type floating channel PMOSFET, compared to when the reverse body bias is not applied. The junction leakage current characteristics may improve as the magnitude of the reverse body bias increases. The graph also shows that the on-current characteristics may not be significantly changed when the reverse body bias is applied to the body region.

FIG. 11 is a graph showing threshold voltage (Vt) characteristics of an MBC-type PMOSFET operated according to some embodiments of the present invention. As shown in FIG. 11, the threshold voltage characteristics may not significantly change with a reverse bias is applied to the body region.

Embodiments of the present invention may provide several advantages. First, a manufacturing process for a transistor may be simplified and durability of the transistor may be improved, as a high concentration-doping region is not required to provide channel isolation in a body region on a substrate. Second, the channel may be electrically isolated by applying a reverse body bias to a body region without forming a high concentration-doping region in a body region of the substrate. Third, junction leakage current characteristics may be improved by applying a reverse body bias to a body region of the substrate, and off-current characteristics may be improved without changing the on-current characteristics and the threshold voltage characteristics of the transistor.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method of operating a transistor that includes at least one fully depleted channel region in and/or on a substrate, the method comprising:
applying a reverse body bias to the substrate when turning on the transistor.

2. The method of claim 1, wherein the substrate is a bulk wafer substrate.

3. The method of claim 1, wherein the reverse body bias allows the transistor to turn on while preventing turn on of a parasitic transistor in the substrate.

4. The method of claim 1, wherein the fully depleted channel region is a floating channel region.

5. The method of claim 4, wherein the floating channel region comprises a plurality of vertically or horizontally disposed floating channel regions.

6. The method of claim 4, wherein the floating channel region is surrounded by a gate electrode of the transistor, and a gate insulating layer is interposed between the floating channel region and the gate electrode.

7. The method of claim 1, wherein the fully depleted channel region is disposed in a fin-shaped region contiguous with the substrate.

8. The method of claim 7, wherein a source region and a drain region of the transistor are disposed on respective sides of the fin-shaped region.

9. The method of claim 7, wherein an upper surface of the fully depleted channel region has a groove therein.

10. The method of claim 1, wherein the reverse body bias is sufficient to increase a threshold voltage of the parasitic transistor to above a threshold voltage of the transistor.

11. The method of claim 1, wherein the transistor is a PMOS field effect transistor or a NMOS field effect transistor.

12. A control circuit configured to perform the method of claim 1.

13. A method of operating a transistor including spaced-apart source and drain regions in an active region of a substrate, at least one floating channel region floated with respect to a body region of the substrate and disposed between the source region and the drain region, and a gate electrode on the channel region, the method comprising:
turning on the transistor while applying a reverse body bias to the body region to increase a threshold voltage of a parasitic transistor in the body region.

14. The method of claim 13, wherein the transistor does not include a high concentration-doping region underlying the floating channel region.

15. The method of claim 13, wherein the reverse body bias prevents turn-on of the parasitic transistor when the transistor is on.

16. The method of claim 13, wherein the reverse bias increases a threshold voltage of the parasitic transistor to a level greater than a threshold voltage of the transistor.

17. The method of claim 13, wherein the transistor is a PMOS field effect transistor or an NMOS field effect transistor.

18. The method of claim 13, wherein the transistor comprises a plurality of vertically or horizontally disposed floating channel regions.

19. The method of claim 13, wherein the gate electrode surrounds the floating channel region, and a gate insulation layer is interposed between the gate electrode and the floating channel region.

20. A control circuit configured to perform the method of claim 13.

21. A method of operating a transistor including spaced apart source and drain regions disposed on respective sides of a fin-shaped region contiguous with a body region of a substrate, the fin-shaped region contacting a body region of the substrate and supporting a fully depleted channel region between the source region and the drain region when the transistor is on and a gate electrode on the fully depleted channel region, the method comprising:
turning on the transistor while applying a reverse body bias to the body region to increase a threshold voltage of a parasitic transistor in the body region.

22. The method of claim 21, wherein a high concentration impurity-doping region is not formed at the body region under the fully depleted channel region in the transistor.

23. The method of claim 21, wherein the reverse body bias prevents turn-on of the parasitic transistor.

24. The method of claim 21, wherein the reverse body bias increases a threshold voltage of the parasitic transistor to a level greater than a threshold voltage of the transistor.

25. The method of claim 21, wherein the transistor is a PMOS field effect transistor or an NMOS field effect transistor.

26. The method of claim 21, wherein on an upper surface of the fully depleted channel region of the fin shaped region has a groove therein.
